(19) United States
(12) Patent Application Publication
(10) Pub. No.: US 2025/0024695 A1
(43) Pub. Date: Jan. 16, 2025

(54) LIGHT DETECTION DEVICE AND MANUFACTURING METHOD THEREOF

(71) Applicant: Japan Display Inc., Tokyo (JP)

(72) Inventors: Motochika YUKAWA, Tokyo (JP); Kazuki MATSUNAGA, Tokyo (JP); Genki ASOZU, Tokyo (JP)

(21) Appl. No.: 18/753,064

(22) Filed: Jun. 25, 2024

(30) Foreign Application Priority Data
Jul. 11, 2023 (JP) 2023-113513

(51) Int. Cl. H10K 39/38; H10K 30/88

(52) U.S. Cl. CPC H10K 39/38; H10K 30/88

(57) ABSTRACT

A light detection device includes two adjacent pixels that each include a light receiving element including a lower electrode, an organic light receiving part laminated on the lower electrode, and an upper electrode laminated on the organic light receiving part, and a wall portion that is provided between the two pixels and extends from below an upper surface of the upper electrode included in the light receiving element to above the upper surface of the upper electrode included in the light receiving element.

### CROSS-REFERENCE TO RELATED APPLICATION

The present application claims priority from Japanese application No. 2023-113513 filed on Jul. 11, 2023, the content of which is hereby incorporated by reference into this application.

### BACKGROUND OF THE INVENTION

### 1. Field of the Invention

The present disclosure relates to a light detection device and a method of manufacturing the same.

### 2. Description of the Related Art

A light detection device may include a collimator that transmits a component of light reflected by a detection target, such as a finger, and traveling in a normal direction toward a pixel and shields a component traveling in an oblique direction (see JP2022-23667A). Using the collimator can inhibit crosstalk caused by the components of light traveling in the oblique direction. This can inhibit blur in a detected image, thereby improving detection accuracy.

The collimator is required to be thick enough to shield the oblique light, and thus the thickness of the entire light detection device tends to be large when the collimator is provided on the sensor layer.

### SUMMARY OF THE INVENTION

One of the objects of the present disclosure is to reduce a thickness of a light detection device having a collimating function.

### Solution to Problem

A light detection device according to the present disclosure includes two adjacent pixels that each include a light receiving element including a lower electrode, an organic light receiving part laminated on the lower electrode, and an upper electrode laminated on the organic light receiving part, and a wall portion that is provided between the two pixels and extends from below an upper surface of the upper electrode included in the light receiving element to above the upper surface of the upper electrode included in the light receiving element.

### BRIEF DESCRIPTION OF THE DRAWINGS

FIG. 1A is a plan view of a light detection device indicating an example of a configuration thereof;

FIG. 1B is a block diagram showing an example of functions implemented in the light detection device;

FIG. 2 is a partial sectional view of the light detection device taken along the line II-II line in FIG. 1 of the first embodiment;

FIG. 3 is an enlarged schematic partial sectional view of the detection area in FIG. 2;

FIG. 4 is an enlarged schematic partial sectional view of a wall portion in FIG. 3;

FIG. 5 is an enlarged plan view of an area A surrounded by a broken line in FIG. 1A;

FIG. 6A is a schematic cross-sectional view of the light detection device in a manufacturing process;

FIG. 6B is a schematic cross-sectional view of the light detection device in the manufacturing process;

FIG. 6C is a schematic cross-sectional view of the light detection device in the manufacturing process;

FIG. 6D is a schematic cross-sectional view of the light detection device in the manufacturing process;

FIG. 6E is a schematic cross-sectional view of the light detection device in the manufacturing process;

FIG. 6F is a schematic cross-sectional view of the light detection device in the manufacturing process;

FIG. 7 is an enlarged partial sectional view of the light detection device taken along the line II-II in FIG. 1 in the second embodiment;

FIG. 8 is an enlarged partial sectional view of the light detection device taken along the line II-II in FIG. 1 in the first modification; and

FIG. 9 is an enlarged partial sectional view of the light detection device taken along the line II-II in FIG. 1 in the second modification.

### DETAILED DESCRIPTION OF THE INVENTION

### 1. First Embodiment

Embodiments of the present invention will be described in detail referring to the drawings. In this regard, the present invention is not to be limited to the embodiments described below, and can be changed as appropriate without departing from the spirit of the invention.

The accompanying drawings may schematically illustrate widths, thicknesses, shapes, or other characteristics of each part for clarity of illustration, compared to actual configurations. However, such a schematic illustration is merely an example and not intended to limit the invention according to the present disclosure. In this specification and the drawings, some elements identical or similar to those shown previously are denoted by the same reference signs as the previously shown elements, and thus repetitive detailed descriptions of them may be omitted as appropriate.

Further, in the embodiments, when a positional relationship between a component and another component is defined, if not otherwise stated, the words “on” and “below” suggest not only a case where the another component is disposed immediately on or below the component, but also a case where the component is disposed on or below the another component with a third component interposed therebetween.

### 1-1. Outline of Light Detection Device

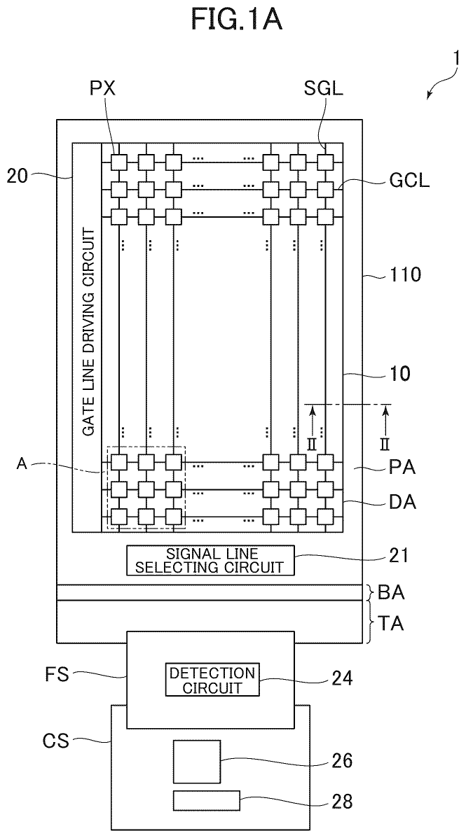

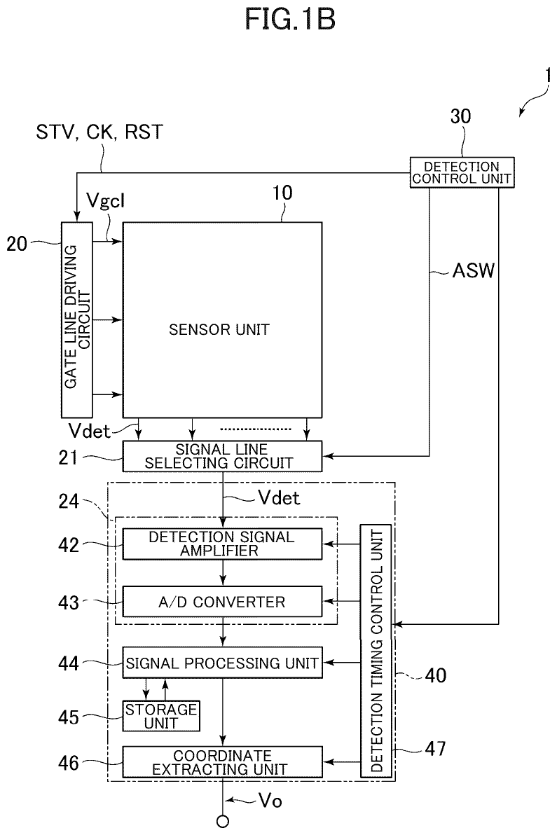

FIG. 1A is a plan view of a light detection device 1 indicating an example of a configuration thereof. FIG. 1B is a block diagram illustrating an example of functions implemented in the light detection device 1.

As shown in FIG. 1A, the light detection device 1 includes a substrate 110, a sensor unit 10, a gate line driving circuit 20, a signal line selecting circuit 21, a detection circuit 24, a control circuit 26, and a power supply circuit 28. The light detection device 1 has a surface irradiation structure.

A control substrate CS is electrically connected to the substrate 110 via a flexible printed board FS. The flexible printed board FS includes the detection circuit 24. The control substrate CS includes the control circuit 26 and the power supply circuit 28. The control circuit 26 is a field programmable gate array (FPGA), for example. The control circuit 26 supplies control signals to the sensor unit 10, the gate line driving circuit 20, and the signal line selecting circuit 21 so as to control the detection operation of the sensor unit 10. The power supply circuit 28 supplies a power supply voltage to the sensor unit 10, the gate line driving circuit 20, and the signal line selecting circuit 21.

The light detection device 1 includes a detection area DA and a frame area PA. The detection area DA is an area in which the sensor unit 10 is provided. The frame area PA is an area outside the detection area DA where the sensor unit 10 is not provided. In other words, the frame area PA is an area between the end portion of the detection area DA and the end portion of the substrate 110. The frame area PA includes a bending area BA and a terminal area TA. The bending area BA and the terminal area TA are provided at one end of the frame area PA. Wires connected to the detection area DA are disposed in the bending area BA and the terminal area TA. The substrate 110 and the flexible printed board FS are connected in the terminal area TA.

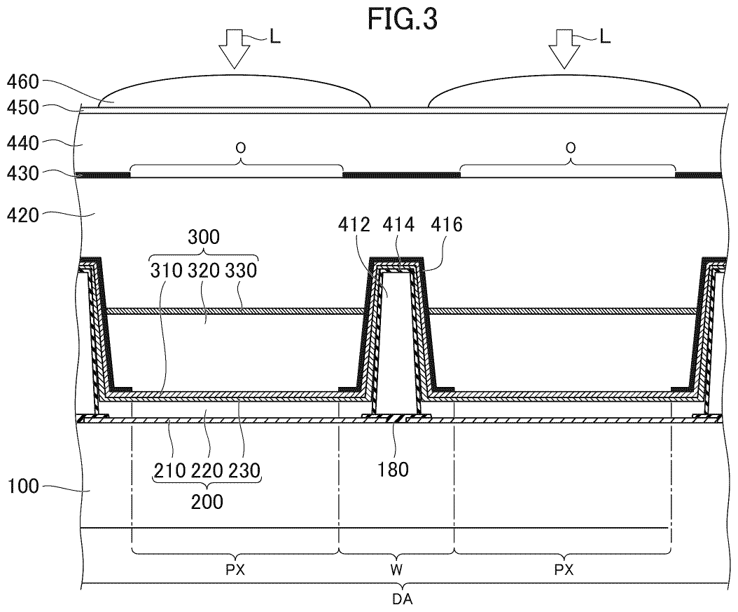

The sensor unit 10 includes a plurality of pixels PX and receives light L from the detection object (see e.g., FIG. 3). The pixels PX are disposed in a matrix in the detection area DA. Each of the pixels PX includes a light receiving element 200 to be described later, and outputs an electric signal corresponding to light irradiated to each pixel. Each pixel PX outputs an electric signal corresponding to the light irradiating the pixel PX to the signal line selecting circuit 21 as a detection signal Vdet. The light detection device 1 may be capable of detecting biological data, such as a blood vessel image of a finger and a palm, a pulse wave, a pulse, and a blood-oxygen saturation, based on the detection signal Vdet from each pixel PX. Each pixel PX performs detection in accordance with a gate drive signal Vgcl supplied from the gate line driving circuit 20.

The gate line driving circuit 20 and the signal line selecting circuit 21 are provided in the frame area PA. Specifically, as shown in FIG. 1A, the gate line driving circuit 20 is provided in an area of the frame area PA extending along the extension direction of the signal line SGL. The signal line selecting circuit 21 is provided in an area of the frame area PA extending along the extension direction of the gate line GCL, and is provided between the sensor unit 10 and the bending area BA.

As shown in FIG. 1B, the light detection device 1 includes a detection control unit 30 and a detection unit 40. Some or all of the functions of the detection control unit 30 are included in the control circuit 26. Further, some or all of the functions of the detection unit 40 other than the detection circuit 24 are included in the control circuit 26.

The detection control unit 30 is a circuit that supplies control signals to the gate line driving circuit 20, the signal line selecting circuit 21, and the detection unit 40, and controls their operations. The detection control unit 30 supplies control signals, such as a start signal STV, a clock signal CK, and a reset signal RST, to the gate line driving circuit 20. The detection control unit 30 supplies control signals, such as a selection signal ASW, to the signal line selecting circuit 21. The gate line driving circuit 20 drives the gate line GCL based on the control signals. The gate line driving circuit 20 sequentially or simultaneously selects a plurality of gate lines GCL, and supplies a gate drive signal Vgcl to the selected gate line GCL. In this manner, the gate line driving circuit 20 selects a pixel PX connected to the gate line GCL. The signal line selecting circuit 21 is a switching circuit that sequentially or simultaneously selects a plurality of signal lines SGL. The signal line selecting circuit 21 is a multiplexer, for example. The signal line selecting circuit 21 connects the selected signal line SGL with the detection circuit 24 based on the selection signal ASW supplied from the detection control unit 30. This enables the signal line selecting circuit 21 to output a detection signal Vdet of the pixel PX to the detection unit 40.

The detection unit 40 includes the detection circuit 24, a signal processing unit 44, a storage unit 45, a coordinate extracting unit 46, and a detection timing control unit 47. The detection timing control unit 47 controls the detection circuit 24, the signal processing unit 44, and the coordinate extracting unit 46 to operate in synchronization based on the control signal supplied from the detection control unit 30.

The detection circuit 24 is an analog front end circuit (AFE), for example. The detection circuit 24 is a signal processing circuit having at least functions of a detection signal amplifier 42 and an A/D converter 43. The detection signal amplifier 42 amplifies the detection signal Vdet. The A/D converter 43 converts an analog signal from the detection signal amplifier 42 into a digital signal. The signal processing unit 44 is a logic circuit that detects a predetermined physical quantity entered into the sensor unit 10 based on the output signal of the detection circuit 24. When a detection target, such as a finger and a palm, comes into contact with or is close to the detection surface, the signal processing unit 44 detects unevenness of the surface of the finger and the palm based on the signal from the detection circuit 24. Further, the signal processing unit 44 detects biological data, such as a blood vessel image of a finger and a palm, a pulse wave, a pulse, and a blood-oxygen saturation, based on a signal from the detection circuit 24. The storage unit 45 temporarily stores the signal calculated by the signal processing unit 44. The storage unit 45 may be a random access memory (RAM) or a register circuit, for example. The coordinate extracting unit 46 is a logic circuit that obtains detection coordinates of unevenness of a surface of a finger and a palm, for example, when the signal processing unit 44 detects contact or approach of the finger or the palm. The coordinate extracting unit 46 is a logic circuit that obtains detection coordinates of blood vessels of a finger and a palm, for example. The coordinate extracting unit 46 combines detection signals Vdet from the respective pixels PX of the sensor unit 10 to generate two-dimensional information indicating the shape of the unevenness of the surface of the finger and the palm, for example. The coordinate extracting unit 46 may not calculate the detection coordinates but output the detection signal Vdet as the sensor output Vo.

### 1-2. Detailed Structure of Light Detection Device

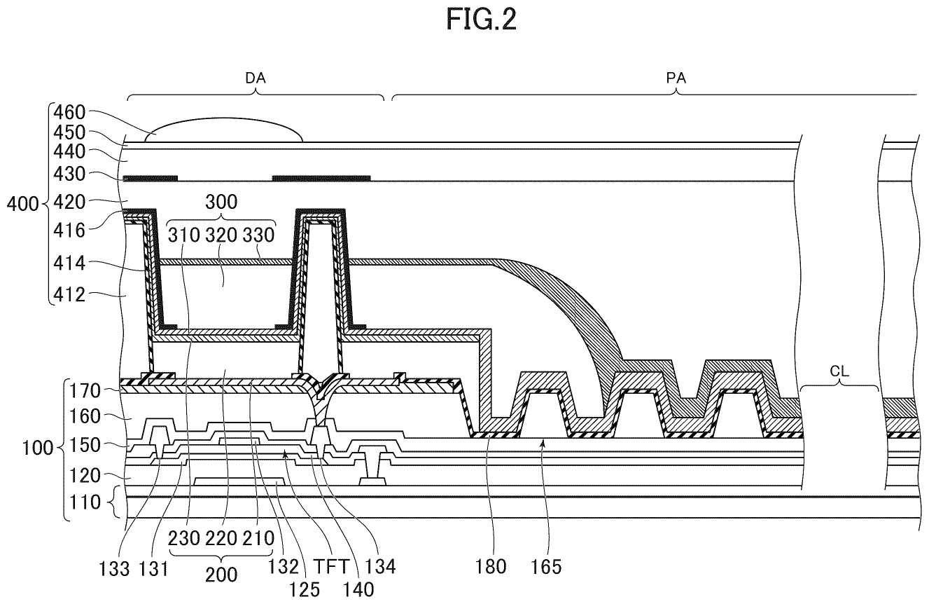

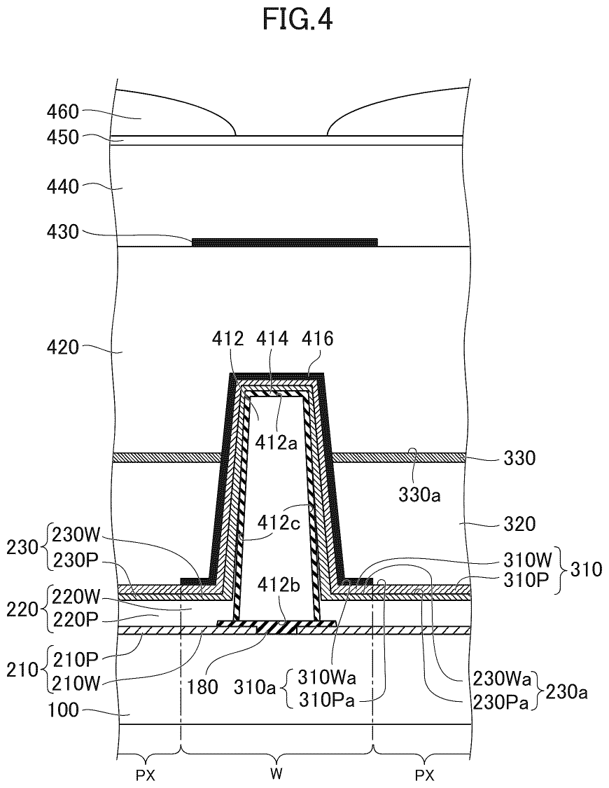

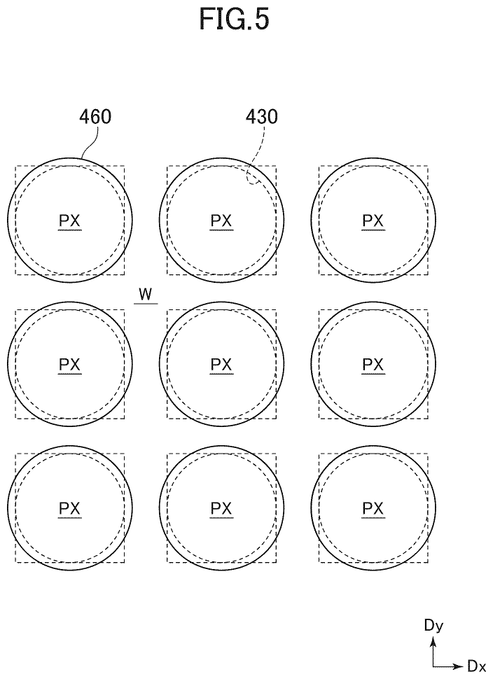

Referring to FIGS. 2 and 3, the cross-sectional structure of the light detection device 1 will be described in order from the lower layer. FIG. 2 is a partial sectional view of the light detection device 1 taken along the line II-II line in FIG. 1 of the first embodiment. FIG. 3 is an enlarged schematic partial sectional view of the detection area DA in FIG. 2. FIG. 4 is an enlarged schematic partial sectional view of the wall portion W in FIG. 3. FIG. 5 is an enlarged plan view of the area A surrounded by the broken line in FIG. 1A. FIG. 2 shows a part of the detection area DA near the end portion and a part of the frame area PA. In FIG. 2, hatching of some layers is omitted for clarity of the cross-sectional structure (the same applies to FIGS. 3, 4, 6 to 9 described later).

The light detection device 1 includes a circuit layer 100, a light receiving element 200, a sealing portion 300, and a collimator 400.

### 1-2-1. Circuit Layer

The circuit layer 100 includes the substrate 110, a barrier inorganic layer 120, an additional film 125, a thin film transistor TFT, a gate insulating layer 140, an interlayer insulating layer 150, a flattening layer 160, and an insulating layer 170.

For example, the substrate 110 may have a two-layer structure of a glass substrate and a resin substrate laminated thereon. The resin substrate may be formed of polyimide, for example. However, the present invention is not limited thereto, and the substrate 110 may not have a glass substrate and may be formed of only a flexible resin substrate.

A barrier inorganic layer 120 is laminated on the substrate 110. The barrier inorganic layer 120 may have a laminate structure including a plurality of layers. The additional film 125 may be formed at a portion where the thin film transistor TFT to be described later is formed.

The thin film transistor TFT includes a semiconductor layer 131, a gate electrode 132, a source electrode 133, and a drain electrode 134. A gate insulating layer 140 is provided between the semiconductor layer 131 and the gate electrode 132. A silicon oxide layer may be used as the gate insulating layer 140. An interlayer insulating layer 150 is laminated on the gate electrode 132. The interlayer insulating layer 150 may have a laminate structure of a silicon nitride layer and a silicon oxide layer.

The flattening layer 160 is provided to cover the interlayer insulating layer 150. The flattening layer 160 may be made of resin, such as photosensitive acrylic, having excellent surface flatness. The flattening layer 160 may be removed at a portion that electrically connects the light receiving element 200 and the circuit layer 100. The end portions of the flattening layer 160 may be positioned in the frame area PA. Also, the flattening layer 160 may be partially removed in the frame area PA.

The insulating layer 170 is laminated on the flattening layer 160. The inorganic insulating layer 180 made of an inorganic material is laminated on the insulating layer 170. The inorganic insulating layer 180 is also laminated on the lower electrodes 210 so as to expose each of the lower electrodes 210. The inorganic insulating layer 180 may be laminated on the flattening layer 160 in the frame area PA.

### 1-2-2. Light Receiving Element

The pixels PX each include a light receiving element 200 including a lower electrode 210 laminated on the insulating layer 170, an organic light receiving part 220 laminated on the lower electrode 210, and an upper electrode 230 laminated on the organic light receiving part 220. The lower electrode 210 and the organic light receiving part 220 are commonly provided in the pixels PX. The upper electrode 230 is commonly provided in the pixels PX. The organic light receiving part 220 is a layer that functions as a photoelectric conversion layer. The lower electrode 210 is electrically connected to the drain electrode 134 of the circuit layer 100. The upper electrode 230 has a light-transmitting property. The lower electrode 210 includes a part 210P that constitutes a pixel PX and a part 210W that constitutes a wall portion W to be described later. The organic light receiving part 220 includes a part 220P that constitutes a pixel PX and a part 220W that constitutes a wall portion W to be described later. The upper electrode 230 has a part 230P that constitutes a pixel PX and a part 230W that constitutes a wall portion W (see FIG. 4) to be described later. The upper surface 230a of the upper electrode 230 has an upper surface 230Pa of the part 230P and an upper surface 230Wa of the part 230W.

### 1-2-3. Sealing Portion

The plurality of pixels PX each include a sealing portion 300 including a first inorganic sealing film 310 laminated on the upper electrode 230, a resin film 320 laminated on the first inorganic sealing film 310, and a second inorganic sealing film 330 laminated on the resin film 320. The first inorganic sealing film 310 is commonly provided on the pixels PX. The resin film 320 and the second inorganic sealing film 330 are provided for each pixel PX. That is, the resin film 320 and the second inorganic sealing film 330 are laminated on the first inorganic sealing film 310 above each organic light receiving part 220.

The first inorganic sealing film 310 has a part 310P that constitutes a pixel PX and a part 310W that constitutes a wall portion W to be described later.

The sealing portion 300 is provided on the light receiving side, and is thus preferably formed of a material that does not absorb the light of the wavelength to be detected, for example. In the first embodiment, the first inorganic sealing film 310, the resin film 320, and the second inorganic sealing film 330 each have a light-transmitting property.

### 1-2-4. Collimator

The collimator 400 includes a core portion 412, a moisture-proof film 414, a light-shielding film 416, a first transparent resin layer 420, a light-shielding layer 430, a second transparent resin layer 440, a foundation layer 450, and a lens 460. The core portion 412, the moisture-proof film 414, and the light-shielding film 416 constitute a wall portion W.

The wall portion W extends from below the upper surface 230Pa of the upper electrode 230 included in the light receiving element 200 to above the upper surface 230Pa of the upper electrode 230 included in the light receiving element 200 between two adjacent pixels PX (see FIG. 4). In the first embodiment, the part 230W of the upper electrode 230 forms the wall portion W, and thus the wall portion W extends from below the upper surface 230Pa of the part 230P constituting the pixels PX of the upper electrode 230 to above the upper surface 230Pa of the part 230P constituting the pixels PX of the upper electrode 230 between the two adjacent light receiving elements 200 (see FIG. 4). More specifically, the wall portion W extends from below the upper surface 230Pa of the part 230P of the upper electrode 230 to above the upper surface 330a of the second inorganic sealing film 330. The wall portion W is provided so as to surround each pixel PX in a plan view (see FIG. 5).

The wall portion W is made of resin and includes a core portion 412 extending from below the upper surface 230Pa of the upper electrode 230 included in the light receiving element 200 to above the upper surface 230Pa of the upper electrode 230 included in the light receiving element 200. Specifically, the core portion 412 extends from below the upper surface 230Pa of the part 230P constituting the pixels PX of the upper electrode 230 to above the upper surface of the part 230P constituting the pixels PX of the upper electrode 230 (see FIG. 4). More specifically, the core portion 412 extends from below the upper surface 230Pa of the part 230P of the upper electrode 230 to above the upper surface 330a of the second inorganic sealing film 330. The core portion 412 is laminated on the inorganic insulating layer 180 provided between two adjacent lower electrodes 210. In the first embodiment, the core portion 412 is made of resin having a light-transmitting property. For example, the core portion 412 may be made of resin such as photosensitive acrylic as in the flattening layer 160.

More specifically, the core portion 412 has a top portion 412a positioned above the upper surface 330a of the second inorganic sealing film 330, a bottom portion 412b positioned below the upper surface 230Pa of the upper electrode 230 included in the light receiving element 200, and two side portions 412c connecting the top portion 412a and the bottom portion 412b (see FIG. 4). That is, the core portion 412 has a quadrangular shape in a cross-sectional view. In FIGS. 2 and 3, the core portion 412 has a tapered shape in the cross-sectional view, although the core portion 412 may have an inverted tapered shape or a rectangular shape in the cross-sectional view.

The wall portion W includes a moisture-proof film 414 interposed between the core portion 412 and the organic light receiving parts 220 included in the respective pixel PX. The moisture-proof film 414 is laminated so as to cover at least two side portions 412c of the core portion 412 (see FIG. 4). Specifically, the moisture-proof film 414 is laminated so as to cover the two side portions 412c and the top portion 412a of the core portion 412. The moisture-proof film 414 is made of a material having a higher moisture-proof property than the core portion 412. For example, the moisture-proof film 414 may be made of silicon nitride or alumina. As described above, the moisture-proof film 414 disposed between the core portion 412 and the organic light receiving part 220 can prevent moisture from entering the organic light receiving part 220 through the core portion 412 made of resin, which is porous and easily allows moisture to pass therethrough.

The wall portion W includes a light-shielding film 416 having a light-shielding property and covering a part of each side portion 412c of the core portion 412 and the top portion 412a. The light-shielding film 416 has a property of absorbing light (see FIG. 4). In the first embodiment, the light-shielding film 416 is made of metal such as chromium, although the light-shielding film 416 may be made of black resin, for example. The light-shielding film 416 may have a property of reflecting light. In the first embodiment, the light-shielding film 416 covers a part of the side portions 412c of the core portion 412 that extends to above the upper surface 230Pa of the upper electrode 230 included in the light receiving element 200. On the other hand, the light-shielding film 416 does not cover a part of the side portions 412c of the core portion 412 that extends to below the upper surface 230Pa of the upper electrode 230 included in the light receiving element 200. Further, a part of the light-shielding film 416 is laminated on the upper surface 310Wa of the part 310W of the first inorganic sealing film 310 that constitutes the wall portion W. As described above, the light-shielding film 416 covers the wall portion W, and thus it is possible to more suitably prevent oblique light from entering the pixels PX.

The light-shielding film 416 may cover only the top portion 412a of the core portion 412. The light-shielding film 416 may cover only a part of one of the two side portions 412c of the core portion 412.

The first transparent resin layer 420 is laminated on the sealing portion 300. The first transparent resin layer 420 is also laminated on a part of the light-shielding film 416 located on the upper surface 330a of the second inorganic sealing film 330. The second transparent resin layer 440 is laminated on the first transparent resin layer 420. Similarly to the flattening layer 160, the first transparent resin layer 420 and the second transparent resin layer 440 may be made of resin such as photosensitive acrylic having excellent surface flatness.

The light-shielding layer 430 is laminated on the first transparent resin layer 420. The light-shielding layer 430 is provided above the wall portion W and has one opening O in an area above the sealing portion 300. The opening O is provided so as to correspond to each of the pixels PX. The light-shielding layer 430 has a property of absorbing light. In the first embodiment, similarly to the light-shielding film 416, the light-shielding layer 430 is made of metal such as chromium, although the light-shielding layer 430 may be formed of a film made of black resin, for example. The light-shielding layer 430 may have a property of reflecting light.

As shown in FIGS. 3 and 5, the light-shielding layer 430 is provided so as to surround each of the light receiving elements 200 in a plan view. The light-shielding layer 430 is provided so as to overlap the wall portion W in a plan view. As shown in FIG. 5, the opening O of the light-shielding layer 430 has a circular shape, although the shape of the opening O is not limited to this example, and may be a square shape, for example.

The foundation layer 450 is laminated on the second transparent resin layer 440. The foundation layer 450 may be made of an organic material. The organic material used as the foundation layer 450 can improve adhesion to the lens 460, which will be described later. Further, the organic material used as the foundation layer 450 can improve the processability of the lens 460. The foundation layer 450 may be made of an inorganic material. The organic material used as the foundation layer 450 further improves moisture-proof property.

The lens 460 is laminated on the foundation layer 450. The lens 460 is provided above the light-shielding layer 430 so as to overlap the opening O in a plan view (see FIG. 3). In the first embodiment, the lens 460 is a convex lens. The lens 460 has a circular shape in a plan view. The diameter of the lens 460 is larger than the diameter of the opening O. A part of the light L reflected by the detection object, such as a finger, is collected by the lens 460 and passes through the opening O to enter the light receiving element 200 (see FIG. 3).

As shown in FIG. 2, the flattening layer 160 and the inorganic insulating layer 180 formed along the flattening layer 160 form a protrusion 165 in the frame area PA. The protrusion 165 may be formed by removing a portion of the flattening layer 160 formed in the frame area PA and providing the inorganic-insulating layer 180 on the remaining portion of the flattening layer 160. The protrusion 165 is formed to prevent the resin constituting the light-receiving element 200 and the sealing portion 300 from leaking out of the frame area PA when the layers are formed. FIG. 2 shows an example in which three protrusions 165 are formed side by side toward the outside, but the number of protrusions 165 is not limited thereto. Alternatively, the protrusion 165 may not be provided. That is, the flattening layer 160 may not be provided in the frame area PA.

As shown in FIG. 2, in the first embodiment, the first inorganic sealing film 310 and the second inorganic sealing film 330 are formed so as to be along the shapes of the protrusions 165 in the frame area PA. As described above, the inorganic layer is formed along the unevenness caused by the protrusions 165, and the moisture-proof property is thereby improved.

FIG. 2 shows an example in which a cut line CL is formed so as to surround the detection area DA in the frame area PA. The layers above the substrate 110 are removed in the cut line CL. However, the configuration of the frame area PA is not limited to the example shown in FIG. 2.

### 1-3. Manufacturing Method of Light Detection Device

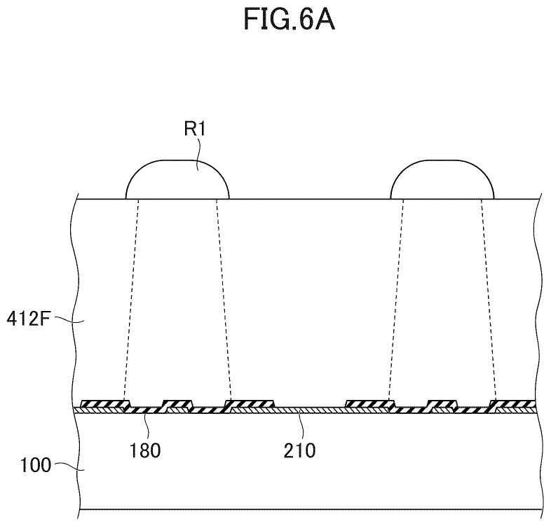

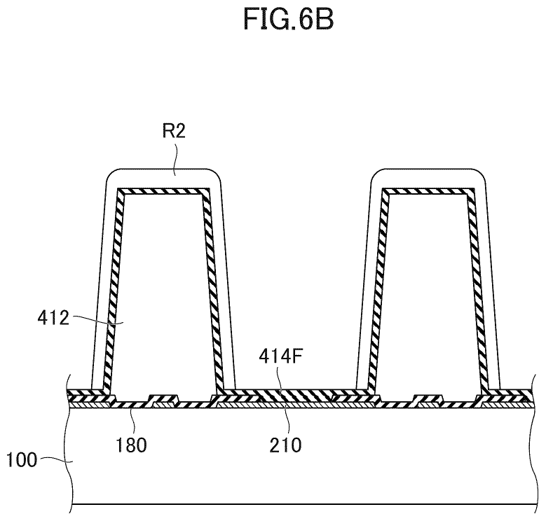

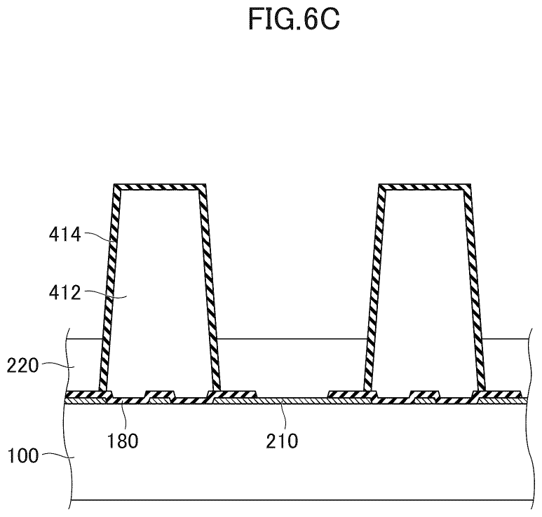

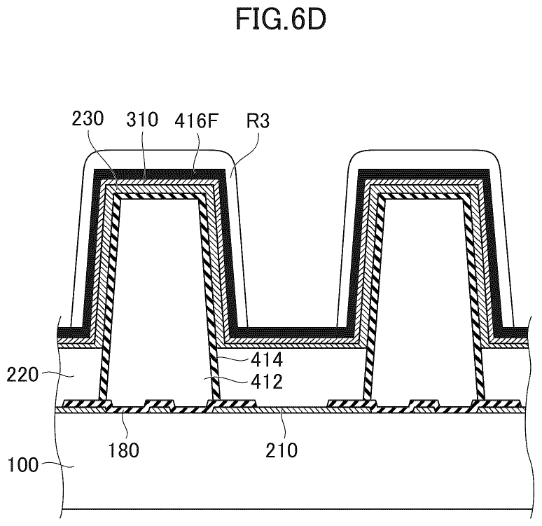

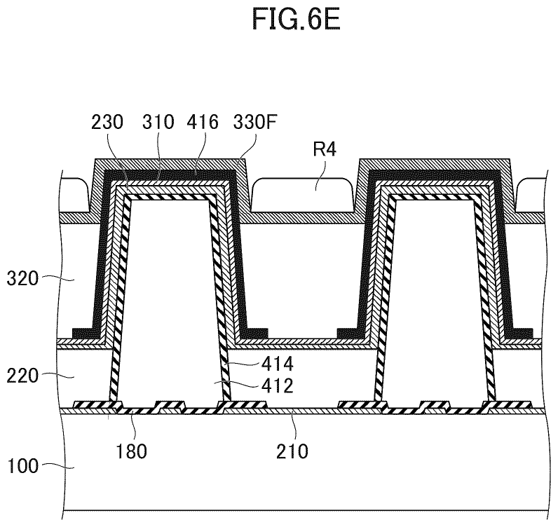

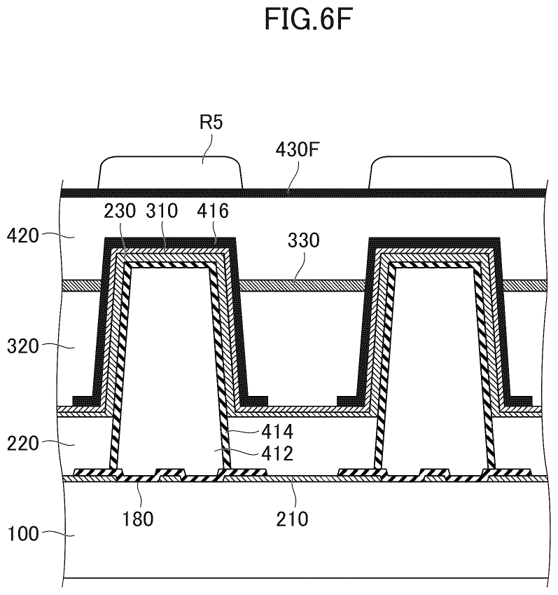

With reference to FIGS. 6A to 6F, an example of the manufacturing processing of the light detection device 1 of the first embodiment will be described. FIGS. 6A to 6F are schematic cross-sectional views of the light detection device 1 in the manufacturing processes.

First, a plurality of lower electrodes 210 are formed on the circuit layer 100. Next, an inorganic insulating layer 180 is formed on the circuit layer 100 so as to expose a part of each lower electrode 210. A resin 412F is then applied over the lower electrodes 210 and the inorganic insulating layer 180 (see FIG. 6A). A protective film R1 is formed on the resin 412F, which is then etched to form a core portion 412 extending above the circuit layer 100. The protective film R1 is formed at a position on the resin 412F corresponding to a position where the core portion 412 is formed. As shown in FIGS. 3 and 5, the core portion 412 surrounds each of the lower electrodes 210 in a plan view. The protective film R1 may be a photoresist, for example.

Subsequently, as shown in FIG. 6B, an inorganic film 414F is commonly formed over the core portion 412 and the lower electrodes 210. The inorganic film 414F may be formed by a CVD method, for example. After the protective film R2 is formed so as to cover the core portion 412, the inorganic film 414F is etched to form the moisture-proof film 414.

As shown in FIG. 6C, a plurality of organic light receiving parts 220 are formed on the respective lower electrodes 210 surrounded by the core portions 412 in a plan view so as not to exceed the top portion 412a of the core portion 412. The organic light receiving part 220 may be formed by applying an organic material by ink-jet, for example. The core portion 412 is disposed to mask between two adjacent lower electrodes 210, and the organic light receiving part 220 is thereby formed for each pixel PX.

Subsequently, as shown in FIG. 6D, the upper electrode 230 is commonly formed over the core portions 412 and the plurality of organic light receiving parts 220. Further, a first inorganic sealing film 310 is formed on the upper electrode 230, and a metallic film 416F is formed on the first inorganic sealing film 310. After the protective film R3 is formed so as to cover the core portion 412, the metallic film 416F is etched to form the light-shielding film 416. The upper electrode 230, the first inorganic sealing film 310, and the metallic film 430F may be formed by a CVD method, for example.

Next, as shown in FIG. 6E, a plurality of resin films 320 are formed so as to be laminated on the first inorganic sealing film 310 above each of the organic light receiving parts 220. The resin films 320 are formed so as not to exceed the top portion 412a of the core portion 412. Similarly to the organic light receiving part 220, each of the resin films 320 may be formed by applying a resin material by ink-jet, for example. Subsequently, an inorganic film 330F is commonly formed over the core portion 412 and the resin films 320. The protective film R4 is formed so as to be laminated on the inorganic film 330F above the respective resin films 320, and then the inorganic film 330F is etched to form the second inorganic sealing film 330. The inorganic film 330F may be formed by a CVD method, for example. As shown in FIG. 3, the second inorganic sealing film 330 is patterned so as to be formed only on the pixels PX, and this serves to prevent the wall portion W from being thicker as a whole. Further, the inorganic film 330F may be formed over the entire detection area DA so as to cover the wall portion W, that is, to be laminated on the light-shielding film 416 on the top portion 412a of the core portion 412. In FIG. 6E, this structure is before the protective film R4 is provided.

As shown in FIG. 6F, the first transparent resin layer 420 is formed on the second inorganic sealing film 330. The first transparent resin layer 420 may be formed by a slit coater, for example. Further, the metallic film 430F is formed on the first transparent resin layer 420. The protective film R5 is formed on the metal film 430F above the core portion 412, and the metal film 430F is then etched to form the light-shielding layer 430. The protective film R5 is formed so as to avoid a portion where the opening O of the light-shielding layer 430 is formed. Subsequently, the second transparent resin layer 440, the foundation layer 450, and the lens 460 are sequentially formed.

### 1-4. SUMMARY OF FIRST EMBODIMENT

As described above, in the first embodiment, the wall portion W is provided so as to extend from below the upper surface 230Pa of the upper electrode 230 included in the light receiving element 200 to above the upper surface 230Pa of the upper electrode 230 included in the light receiving element 200 between two adjacent pixels PX. This serves to prevent oblique light from entering the pixels PX. Accordingly, the layers provided above the light receiving element 200 (e.g., light-shielding layer 430, lens 460) can be made thin or eliminated, and the entire collimator 400 can be thereby made thin. This allows the light detecting device 1 itself to be made thin.

### 2. Second Embodiment

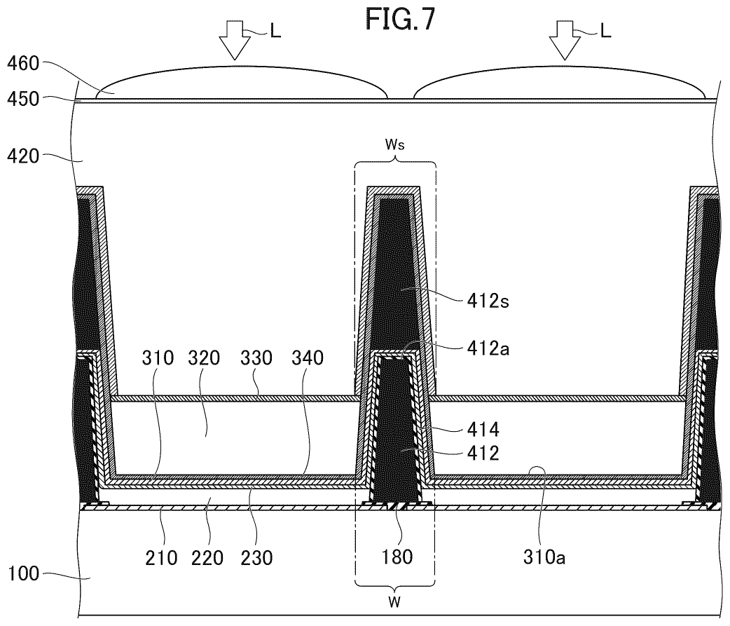

The light detection device 1 according to the second embodiment will be described. FIG. 7 is an enlarged partial sectional view of the light detection device 1 taken along the line II-II in FIG. 1 in the second embodiment. In the following, the same structure as that of the first embodiment will not be described.

In the second embodiment, the core portion 412 of the wall portion W has a light-shielding property. In the second embodiment, the core portion 412 has a light-absorbing property. In the second embodiment, the core portion 412 is made of black resin, although the core portion 412 may be made of metal, such as chrome, similarly to the light-shielding film 416 and the light-shielding layer 430 of the first embodiment. The core portion 412 may have a property of reflecting light. As described above, the core portion 412 has the light shielding property, which serves to more suitably prevent the oblique light from entering the pixels PX. In a case where the core portion 412 can be formed to have a sufficient height, the light-shielding layer 430 and the lens 460 need not be provided above the light receiving element 200, and thus the entire collimator 400 can be made thinner. This allows the entire device to be made thinner.

If there is a need to protect the lower layer of the core portion 412 (e.g., lower electrode 210) from contamination due to the light-shielding material, the core portion 412 is preferably formed of a light-transmitting material as described in the embodiment 1.

As shown in FIG. 7, in the second embodiment, an auxiliary wall portion Ws extending upward is provided above the wall portion W. The auxiliary wall portion Ws includes a core portion 412s. Specifically, the core portion 412s of the auxiliary wall portion Ws is laminated on the upper surface 310a of the first inorganic sealing film 310 and extends upward above the top portion 412a of the core portion 412 of the wall portion W. Similarly to the wall portion W, the auxiliary wall portion Ws is provided so as to surround each of the light receiving elements 200 in a plan view. That is, the auxiliary wall portion Ws includes a row-direction extension portion extending in a first direction Dx and a column-direction extension portion extending in a second direction Dy. The row-direction extension portion and the column-direction extension portion intersect with each other so as to surround each of the light-receiving elements 200 in a plan view. In FIG. 7, a part of the first inorganic sealing film 310 and a part of the third inorganic sealing film 340 also constitute the auxiliary wall portion Ws.

In the second embodiment, assume that the wall portion W and the auxiliary wall portion Ws can provide adequate light shielding performance. As such, unlike the first embodiment, the collimator 400 does not include the light-shielding layer 430 and the second transparent resin layer 440.

According to the light detection device 1 of the second embodiment described above, the layers are favorably laminated on the wall portion W. That is, when the wall portion W is formed higher, the light shielding performance increases, while the part 230W of the upper electrode 230 are not laminated well on the wall portion W. In the second embodiment, a sufficient height for light shielding is not obtained by the wall portion W only, but obtained by a combination of the auxiliary wall portion Ws and the wall portion W. With such a configuration, the lamination described above can be improved.

In the second embodiment, the third inorganic sealing film 340 is laminated on the first inorganic sealing film 310 and the auxiliary wall portion Ws in view of the sealing performance, but the third inorganic sealing film 340 may not be provided.

### 3. Modification

The present disclosure is not limited to the embodiments described above. The present disclosure may be changed as appropriate without departing from the spirit of the present disclosure.

### 3-1. First Modification

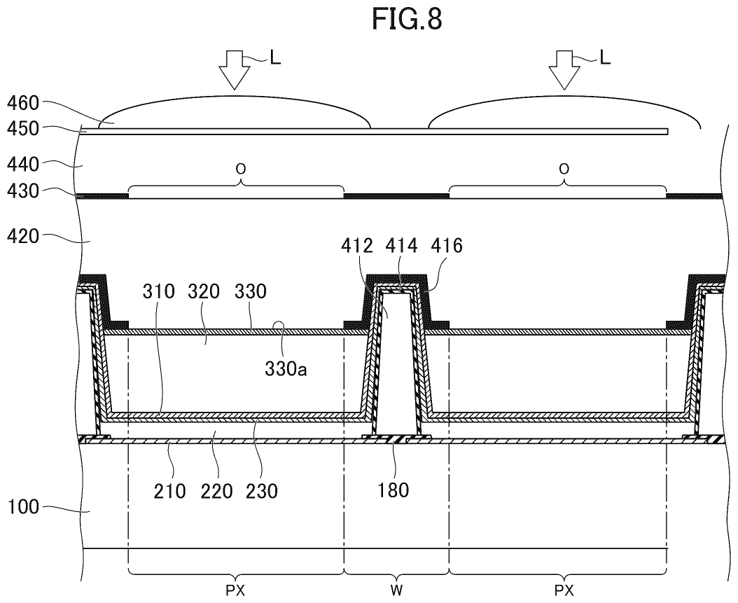

FIG. 8 shows a partial cross section in which the cut surface taken along the line II-II in FIG. 1 according to the first embodiment is schematically enlarged. In the following, the same structure as that of the first embodiment will not be described.

As shown in FIG. 8, in the first modification, the light-shielding film 416 covers a part of the core portion 412 above the upper surface 330a of the second inorganic sealing film 330. The light-shielding film 416 is laminated on the upper surface 330a of the second inorganic sealing film 330. In other words, in the first modification, the light-shielding film 416 is formed after the second inorganic sealing film 330, i.e., the sealing portion 300 is formed. This can improve the sealing performance of the sealing portion 300.

### 3-2. Second Modification

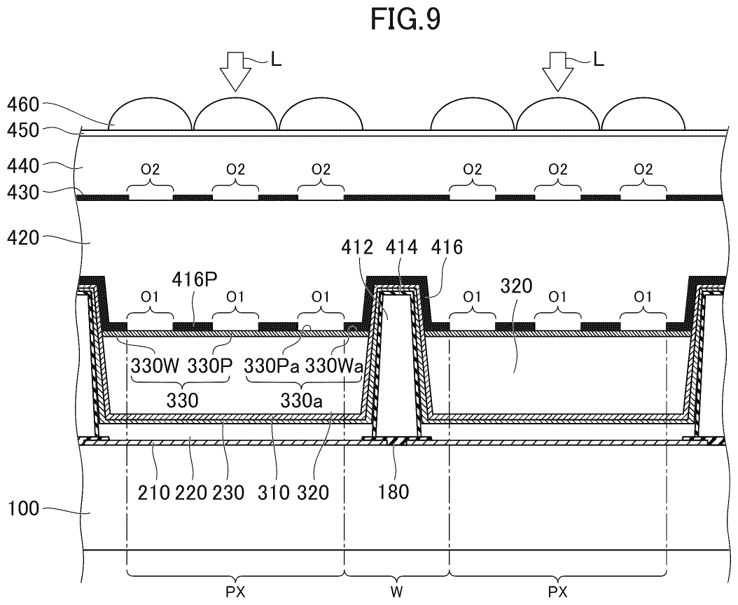

FIG. 9 shows a partial cross section in which the cut surface taken along the line II-II in FIG. 1 according to the second embodiment is schematically enlarged. In the following, the same structure as that of the first embodiment will not be described.

As shown in FIG. 9, in the second modification, a part 416P of the light-shielding film 416 laminated on the second inorganic-sealing film 330 has a plurality of openings O1. In this modification, the second inorganic sealing film 330 has a part 330P constituting the pixel PX and a part 330W constituting the wall portion W. The upper surface 330a of the second inorganic sealing film 330 has an upper surface 330Pa of the part 330P and an upper surface 330Wa of the part 330W. A part 416P of the light-shielding film 416 is laminated on the upper surface 330Pa of the second inorganic sealing film 330 and has a plurality of openings O1. The light-shielding layer 430 has a plurality of openings O2 above the sealing portion 300. The openings O2 are provided so as to correspond to the respective openings O1. Further, lenses 460 are provided above the light-shielding layer 430 so as to overlap the respective openings O2 in a plan view. According to the second modification, the number of openings per pixel PX increases, and the resolution is thereby further improved. The number of the openings is not limited to the example shown in FIG. 8, and may be any number.

While there have been described what are at present considered to be certain embodiments of the invention, it will be understood that various modifications may be made thereto, and it is intended that the appended claims cover all such modifications as fall within the true spirit and scope of the invention.

What is claimed is:

1. A light detection device comprising:
two adjacent pixels that each include a light receiving element including a lower electrode, an organic light receiving part laminated on the lower electrode, and an upper electrode laminated on the organic light receiving part; and
a wall portion that is provided between the two pixels and extends from below an upper surface of the upper electrode included in the light receiving element to above the upper surface of the upper electrode included in the light receiving element.

2. The light detection device according to claim 1, wherein
the wall portion is provided so as to surround at least one of the pixels in a plan view.

3. The light detection device according to claim 1, wherein
the wall portion further includes a core portion that is made of resin and extends from below the upper surface of the upper electrode included in the light receiving element to above the upper surface of the upper electrode included in the light receiving element.

4. The light detection device according to claim 3, wherein
the wall portion further includes a moisture-proof film between the core portion and the organic light receiving part included in at least one of the pixels.

5. The light detection device according to claim 3, wherein
the core portion has a light-transmitting property, and
the wall portion further includes a light-shielding film having a light-shielding property and covering at least a top portion of the wall portion.

6. The light detection device according to claim 5, wherein
the light-shielding film further covers at least a part of at least one of two side portions of the core portion.

7. The light detection device according to claim 5, further comprising:
a sealing portion that is laminated on at least one light receiving element; and
a light-shielding layer that is provided above the wall portion and includes one or more openings in an area above the sealing portion, wherein
the wall portion extends to above an upper surface of the sealing portion.

8. The light detection device according to claim 7, further comprising a lens that is provided above the light-shielding layer so as to overlap each of the openings in a plan view.

9. The light detection device according to claim 5, wherein
at least one of the pixels further includes a sealing portion laminated on the light receiving element included in the pixel,
the core portion extends to above an upper surface of the sealing portion, and
the light-shielding film covers a part of the core portion above the upper surface of the sealing portion.

10. The light detection device according to claim 9, wherein
the light-shielding film includes a part that is laminated on the sealing portion, and
the part includes one or more openings.

11. The light detection device according to claim 3, wherein
the core portion has a light-shielding property.

12. The light detection device according to claim 11, further comprising an auxiliary wall portion that is provided above the wall portion and extends upward.

13. A method of manufacturing a light detection device, comprising:
a lower electrode forming step of forming a plurality of lower electrodes on a substrate;
a wall portion forming step of forming a wall portion that surrounds each of the lower electrodes in a plan view and extends above the substrate;
an organic light receiving part forming step of forming a plurality of organic light receiving parts respectively on the lower electrodes surrounded by the wall portion in a plan view so as not to exceed a top portion of the wall portion; and
an upper electrode forming step of forming an upper electrode commonly on the wall portion and the plurality of organic light receiving parts.
